(19) United States
(12) Patent Application Publication
(10) Pub. No.: US 2026/0324408 A1
(43) Pub. Date: Oct. 15, 2026

(54) SEMICONDUCTOR DEVICE INCLUDING WIRING PROTECTIVE FILM AND METHOD FOR FABRICATING THEREOF

(71) Applicant: SAMSUNG ELECTRONICS CO., LTD., Suwon-si (KR)

(72) Inventors: Young Sang CHO, Suwon-si (KR); Sung Uk JANG, Suwon-si (KR); Min Kyoung LEE, Suwon-si (KR); Woo Jin LEE, Suwon-si (KR)

(73) Assignee: SAMSUNG ELECTRONICS CO., LTD., Suwon-si (KR)

(21) Appl. No.: 19/443,707

(22) Filed: Jan. 8, 2026

(30) Foreign Application Priority Data
Apr. 11, 2025 (KR) 10-2025-0047571

(51) Int. Cl. H10W 20/45; H10W 20/41; H10W 20/43; H10W 20/46; H10W 20/47; H10W 20/48; H10W 20/00

(52) U.S. Cl. CPC H10W 20/455; H10W 20/43; H10W 20/435; H10W 20/46; H10W 20/47; H10W 20/48; H10W 20/072; H10W 20/098

(57) ABSTRACT

To improve element performance and reliability by forming an air gap and a wiring protective film on a side wall of a wiring structure, a semiconductor device may include a lower conductive pattern, a wiring structure on the lower conductive pattern, extending in a first direction, and including upper and bottom surfaces opposing each other in a second direction, the bottom surface of the wiring structure facing the lower conductive pattern, a side wall of the wiring structure connecting the upper and bottom surfaces of the wiring structure, and a first wiring protective film in contact with the wiring structure, and extending along the side wall of the wiring structure, in which the first wiring protective film includes a cover region covering the side wall of the wiring structure, and a plurality of protruding regions, each of which protrudes from the cover region in a third direction.

### CROSS-REFERENCE TO RELATED APPLICATION

This application claims priority from Korean Patent Application No. 10-2025-0047571 filed on Apr. 11, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device and a method for fabricating thereof, and more specifically, to a semiconductor device including line wiring formed in a BEOL (Back-End-Of-Line) process and a method for fabricating thereof.

### 2. Description of the Related Art

With the development of electronic technology, in recent years, as down-scaling of semiconductor elements has progressed rapidly, there is a demand for high integration and low power consumption of the semiconductor chips. In order to cope with the demand for high integration and low power consumption of the semiconductor chips, the feature size of the semiconductor devices continuously decreases.

As various contact forms are used for the connection between the wirings, the length of the contact may become longer. A contact resistance may increase, accordingly.

### SUMMARY

Aspects of the present disclosure provide a semiconductor device that may improve element performance and reliability by forming an air gap and a wiring protective film on a side wall of a wiring structure.

Aspects of the present disclosure also provide a method for fabricating a semiconductor device capable of improving element performance and reliability by forming an air gap and a wiring protective film on the side wall of the wiring structure.

According to an aspect of the present disclosure, there is provided a semiconductor device comprising a lower conductive pattern, a first wiring structure which is disposed on the lower conductive pattern, extends in a first direction, and includes an upper surface and a bottom surface that are opposite to each other in a second direction different from the first direction, the bottom surface of the first wiring structure facing the lower conductive pattern, the first wiring structure further including a side wall connecting the upper surface of the first wiring structure and the bottom surface of the first wiring structure and a first wiring protective film which is in contact with the first wiring structure, and extends along the side wall of the first wiring structure, in which the first wiring protective film includes a cover region that covers the side wall of the first wiring structure, and a plurality of protruding regions, and each of the plurality of protruding regions of the first wiring protective films protrude from the cover region of the first wiring protective film in a third direction different from the first direction and the second direction.

According to another aspect of the present disclosure, there is provided a semiconductor device comprising a lower conductive pattern, a first wiring structure which is disposed on the lower conductive pattern, extends in a first direction, and includes an upper surface and a bottom surface that are opposite to each other in a second direction different from the first direction, the bottom surface of the first wiring structure facing the lower conductive pattern, the first wiring structure further including a side wall connecting the upper surface of the first wiring structure and the bottom surface of the first wiring structure, and a wiring protective film which is in contact with the first wiring structure, and extends along the side wall of the first wiring structure, in which a first thickness of the wiring protective film in a third direction, different from the first direction and the second direction, at a first point of the wiring protective film is greater than a second thickness of the wiring protective film in the third direction at a second point of the wiring protective film, a third thickness of the wiring protective film in the third direction at a third point of the wiring protective film is greater than the second thickness, a height from the bottom surface of the first wiring structure to the first point is smaller than a height from the bottom surface of the first wiring structure to the second point, and a height from the bottom surface of the first wiring structure to the third point is greater than a height from the bottom surface of the first wiring structure to the second point.

According to another aspect of the present disclosure, there is provided a semiconductor device comprising a lower conductive pattern, a first wiring structure which is disposed on the lower conductive pattern and extends in a first direction, a second wiring structure which extends in the first direction, and is spaced apart from the first wiring structure in a second direction perpendicular to the first direction, a wiring protective film which is disposed on the lower conductive pattern, extends along a side wall of the first wiring structure and a side wall of the second wiring structure, and is in contact with the first wiring structure and the second wiring structure, a wiring air gap which is disposed between the first wiring structure and the second wiring structure, a liner capping film which is disposed on the wiring protective film and the wiring air gap, extends along the side wall of the first wiring structure and the side wall of the second wiring structure, and is in contact with the first wiring structure and the second wiring structure and a filling capping film which is disposed on the liner capping film between the first wiring structure and the second wiring structure, in which the wiring protective film includes a cover region that covers the side wall of the first wiring structure, and a plurality of protruding regions, and each of the plurality of protruding region of the wiring protective films protrudes from the cover region of the wiring protective film in the second direction.

According to another aspect of the present disclosure, there is provided a method for fabricating a semiconductor device, the method comprising forming a lower conductive pattern, sequentially forming a metal material film and a capping film on the lower conductive pattern, patterning the metal material film and the capping film to form a plurality of wiring structures, each of which includes a line wiring and a wiring insulation capping film, forming a sacrificial material film between the adjacent wiring structures, the sacrificial material film covering a part of a side wall of the wiring structure, forming a liner capping film on the wiring structure and the sacrificial material film, the liner capping film extending along an upper surface of the wiring structure, an upper surface of the sacrificial material film, and remainder of the side wall of the wiring structure, removing the sacrificial material film to form a wiring air gap between the wiring structures, after forming the wiring air gap, depositing a flowable insulating material to form a filling capping film on the liner capping film and forming a wiring protective film on the side wall of the wiring structure by passage of a part of the flowable insulating material through the liner capping film during the formation of the filling capping film.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail embodiments thereof with reference to the attached drawings, in which:

FIG. 1 is an example layout diagram for explaining a semiconductor device according to some embodiments.

FIG. 2 is a cross-sectional view taken along A-A of FIG. 1.

FIG. 3 is an enlarged view of a portion P of FIG. 2.

FIG. 4 is an enlarged view of a portion Q of FIG. 3.

FIGS. 5 and 6 are diagrams for explaining a semiconductor device according to some embodiments.

FIGS. 7 and 8 are diagrams for explaining the semiconductor device according to some embodiments.

FIGS. 9 and 10 are diagrams for explaining the semiconductor device according to some embodiments.

FIGS. 11 and 12 are diagrams for explaining a semiconductor device according to some embodiments.

FIG. 13 is a diagram for explaining a semiconductor device according to some embodiments.

FIG. 14 is a diagram for explaining a semiconductor device according to some embodiments.

FIG. 15 is a diagram for explaining a semiconductor device according to some embodiments.

FIGS. 16, 17 and 18 are diagrams for explaining a semiconductor device according to some embodiments.

FIGS. 19, 20, 21, 22, 23, 24 and 25 are intermediate stage diagrams for explaining a method for fabricating a semiconductor device according to some embodiments.

### DETAILED DESCRIPTION OF THE EMBODIMENTS

It will be understood that, although the terms "first", "second", "third", and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Although drawings of a semiconductor device according to some embodiments example show a fin-shaped transistor (FinFET) including a channel region of a fin-shaped pattern shape, a transistor including nanowire or nanosheet, a MBCFET^{TM} (Multi-Bridge Channel Field Effect Transistor) or a vertical transistor (Vertical FET), the present disclosure is not limited thereto. The semiconductor device according to some embodiments may, of course, include a tunneling transistor (tunneling FET) or a three-dimensional (3D) stack transistor. The semiconductor device according to some embodiments may, of course, include a planar transistor. In addition, the technical idea of the present disclosure may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

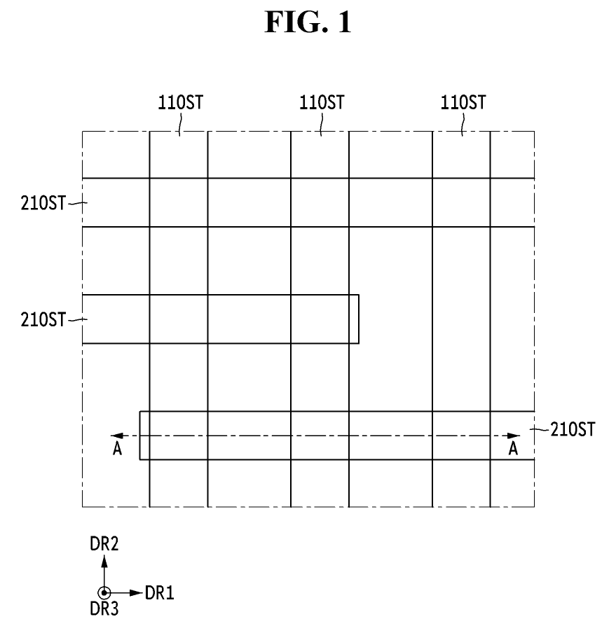

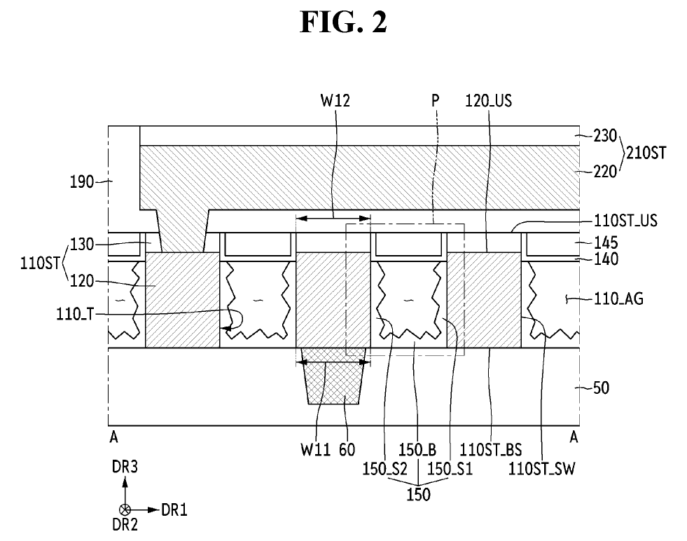

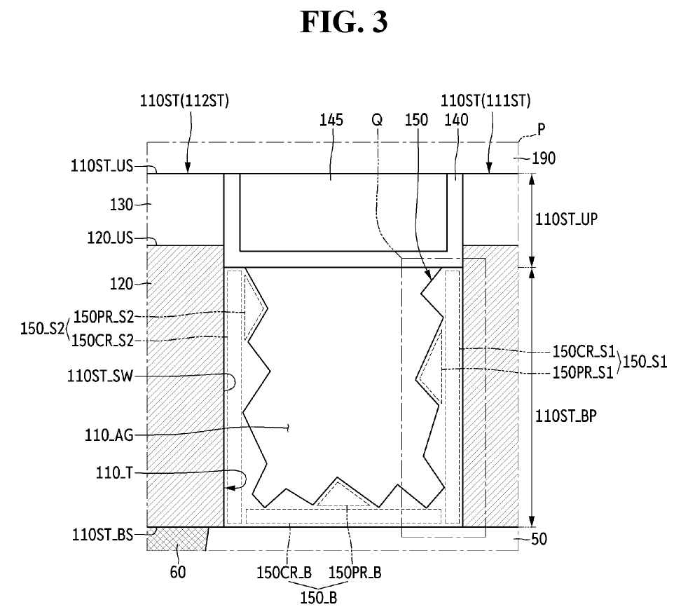

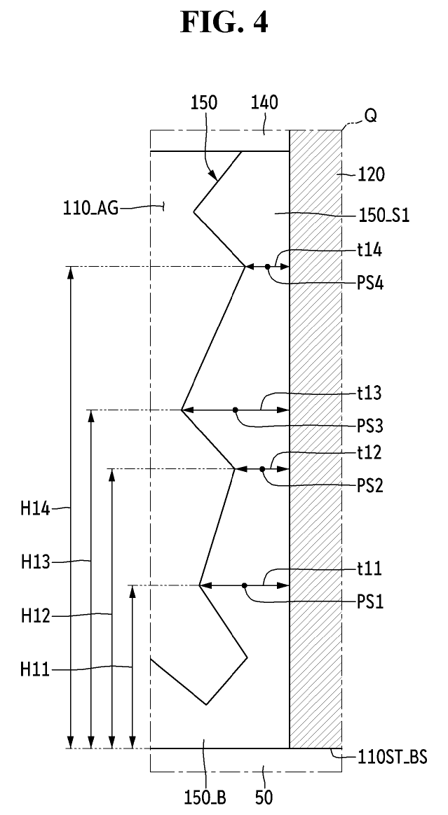

FIG. 1 is an example layout diagram for explaining a semiconductor device according to some embodiments. FIG. 2 is a cross-sectional view taken along A-A of FIG. 1. FIG. 3 is an enlarged view of a portion P of FIG. 2. FIG. 4 is an enlarged view of a portion Q of FIG. 3.

With reference to FIGS. 1-4, the semiconductor device according to some embodiments may include lower wiring structures 110ST, upper wiring structures 210ST, a liner capping film 140, a filling capping film 145, and a wiring protective film 150.

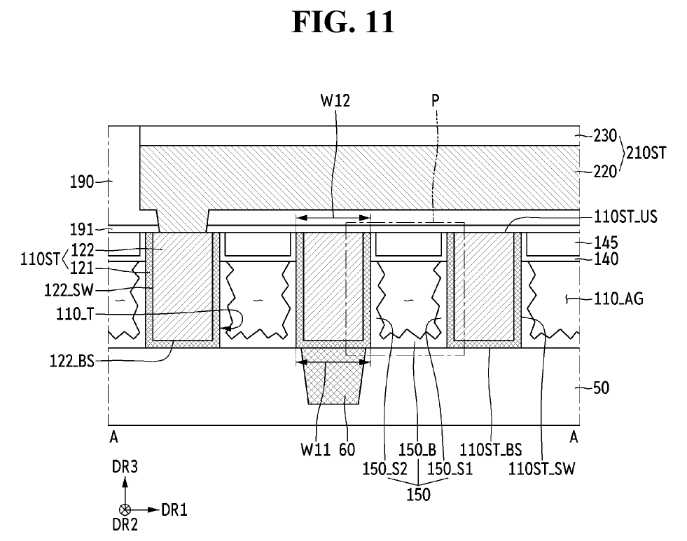

The semiconductor device according to some embodiments may further include a lower interlayer insulating film 50 and a lower conductive pattern 60 disposed inside the lower interlayer insulating film 50. Although the lower conductive pattern 60 is shown as being a single film, this is only for convenience of explanation, and the embodiment is not limited thereto. Unlike the shown example, the lower conductive pattern 60 may include a filling film, and a barrier film extending along the side walls and a bottom surface of the filling film, as in the lower wiring structure 110ST of FIG. 11.

The lower interlayer insulating film 50 may cover a gate electrode and a source/drain of a transistor formed in a front-end-of-line (FEOL) process. Alternatively, the lower interlayer insulating film 50 may be an interlayer insulating film formed in a back-end-of-line (BEOL) process.

In other words, as an example, the lower conductive pattern 60 may be a contact or contact wiring formed in a middle-of-line (MOL) process. As another example, the lower conductive pattern 60 may be a connection wiring formed in the back-end-of-line (BEOL) process.

The lower interlayer insulating film 50 may include, for example, at least one of silicon oxide, silicon nitride, silicon oxynitride or a low dielectric constant material. The low dielectric constant material may be, for example, silicon oxide having moderately high carbon and hydrogen, and may be a material such as SiCOH. On the other hand, since carbon is included in the insulating material, the dielectric constant of the insulating material may be lowered. However, in order to further lower the dielectric constant of the insulating material, the insulating material may include a pore such as a cavity in which gas or air is filled in the insulating material.

The low dielectric constant material may include, for example, but is not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

The lower wiring structures 110ST may be disposed at a first metal level. The lower wiring structures 110ST may be disposed on the lower interlayer insulating film 50. The lower wiring structures 110ST may be connected to the lower conductive pattern 60.

The lower wiring structure 110ST may extend in a second direction DR2. The lower wiring structures 110ST may be spaced apart from each other in the first direction DR1. The lower wiring structures 110ST may be separated in a first direction DR1 by a wiring isolation trench 110_T.

The lower wiring structure 110ST may include an upper surface 110ST_US and a bottom surface 110ST_BS that are opposite to each other in a third direction DR3. The bottom surface 110ST_BS of the lower wiring structure may face the lower conductive pattern 60 and the lower interlayer insulating film 50.

The lower wiring structure 110ST may include a side wall 110ST_SW that connects the bottom surface 110ST_BS of the lower wiring structure and the upper surface 110ST_US of the lower wiring structure. The side wall of the wiring isolation trench 110_T may be defined by the lower wiring structure 110ST.

In the semiconductor device according to some embodiments, a width W11 of the bottom surface 110ST_BS of the lower wiring structure in the first direction DR1 may be equal to a width W12 of the upper surface 110ST_US of the lower wiring structure in the first direction DR1.

The lower wiring structure 110ST may include an upper portion 110ST_UP and a lower portion 110ST_BP. The upper portion 110ST_UP of the lower wiring structure is disposed on the lower portion 110ST_BP of the lower wiring structure. A standard for dividing the upper portion 110ST_UP of the lower wiring structure and the lower portion 110ST_BP of the lower wiring structure will be described below.

For example, the lower wiring structure 110ST may include a lower line wiring 120 and a lower wiring insulation capping film 130.

The lower line wiring 120 may extend long in the second direction DR2. The lower line wiring 120 may have a line shape extending in the second direction DR2. For example, the first direction DR1 may be a width direction of the lower line wiring 120, and the second direction DR2 may be a length direction of the lower line wiring 120.

Here, the first direction DR1 intersects the second direction DR2 and the third direction DR3. The second direction DR2 intersects the third direction DR3. For example, the first direction DR1 may be orthogonal to the second direction DR2 and the third direction DR3. The second direction DR2 may be orthogonal to the third direction DR3.

The lower line wiring 120 may extend long along the upper surface of the lower interlayer insulating film 50. For example, the lower line wiring 120 may be in contact with the upper surface of the lower interlayer insulating film 50.

The lower wiring insulation capping film 130 may be disposed on the lower line wiring 120. The lower wiring insulation capping film 130 may extend along the upper surface 120_US of the lower line wiring.

The bottom surface 110ST_BS of the lower wiring structure may include a bottom surface of the lower line wiring 120. The upper surface 110ST_US of the lower wiring structure may include an upper surface of the lower wiring insulation capping film 130. The lower line wiring 120 and the lower wiring insulation capping film 130 may include a common side wall (e.g., the side wall 110ST_SW) of the lower wiring structure.

For example, the lower line wiring 120 may include at least one of ruthenium (Ru), rhodium (Rh), iridium (Ir), molybdenum (Mo), RuAl, NiAl, NbB₂, MoB₂, TaB₂, V₂AlC, and CrAlC. In the semiconductor device according to some embodiments, the lower wiring 120 may include ruthenium. For example, the lower wiring 120 may be a ruthenium wiring.

Although the lower wiring 120 is shown as being a single film, this is only for convenience of explanation, and the embodiment is not limited thereto. Unlike the shown example, the lower wiring 120 may include a first sub-lower wiring and a second sub-lower wiring. The first sub-lower wiring and the second sub-lower wiring may be sequentially disposed on the lower interlayer insulating film 50 in the third direction DR3. The second sub-lower wiring may be disposed between the first sub-lower wiring and the lower wiring insulation capping film 130. The side walls of the lower wiring 120 may be defined by the first sub-lower wiring and the second sub-lower wiring. The first sub-lower wiring may include at least one of a metal, a metal nitride or a two-dimensional material (2D). The second sub-lower line wiring may include at least one of ruthenium (Ru), rhodium (Rh), iridium (Ir), molybdenum (Mo), tungsten (W), RuAl, NiAl, NbB₂, MoB₂, TaB₂, V₂AlC, and CrAlC.

The lower wiring insulation capping film 130 may include, for example, an insulating material. The lower wiring insulation capping film 130 may include at least one of silicon oxide, silicon nitride, silicon oxynitride or silicon carbonitride. In the semiconductor device according to some embodiments, the lower wiring insulation capping film 130 may include silicon nitride.

The wiring protective film 150 may be disposed on the lower conductive pattern 60 and the lower interlayer insulating film 50. The wiring protective film 150 may be disposed between the lower wiring structures 110ST adjacent to each other in the first direction DR1.

The wiring protective film 150 may be in contact with the lower wiring structure 110ST. For example, the wiring protective film 150 may be in contact with the side wall 110ST_SW of the lower wiring structure.

The wiring protective film 150 may extend along the side wall 110ST_SW of the lower wiring structure. For example, the wiring protective film 150 may extend along a part of the side wall 110ST_SW of the lower wiring structure. The wiring protective film 150 does not extend up to the upper surface 110ST_US of the lower wiring structure.

In other words, the wiring protective film 150 may extend along the side wall of the wiring isolation trench 110_T. The wiring protective film 150 may extend along a part of the side wall of the wiring isolation trench 110_T.

In the semiconductor device according to some embodiments, the wiring protective film 150 may extend along the upper surface of the lower interlayer insulating film 50. The wiring protective film 150 extending along the upper surface of the lower interlayer insulating film 50 may connect the wiring protective film 150 extending along the side wall 110ST_SW of the lower wiring structure facing in the first direction DR1. From the viewpoint of the cross-sectional view, the wiring protective film 150 may have a “U” shape.

The lower portion 110ST_BP of the lower wiring structure may be a portion of the lower wiring structure 110ST that is in contact with the wiring protective film 150. The upper portion 110ST_UP of the lower wiring structure may be in contact with a liner capping film 140 to be described below. The lower portion 110ST_BP of the lower wiring structure and the upper portion 110ST_UP of the lower wiring structure may be divided depending on whether they are in contact with the wiring protective film 150.

The lower wiring structure 110ST may include a first lower wiring structure 111ST and a second lower wiring structure 112ST that are adjacent to each other in the first direction DR1. The first lower wiring structure 111ST may be spaced apart from the second lower wiring structure 112ST in the first direction DR1. The side wall 110ST_SW of the first lower wiring structure 111ST faces the side wall 110ST_SW of the second lower wiring structure 112ST.

The wiring protective film 150 extends along the side wall 110ST_SW of the first lower wiring structure 111ST and the side wall 110ST_SW of the second lower wiring structure 112ST. The wiring protective film 150 may be in contact with the first lower wiring structure 111ST and the second lower wiring structure 112ST.

The wiring protective film 150 may include a first wiring protective film 150_S1 and a second wiring protective film 150_S2.

The first wiring protective film 150_S1 may extend along a part of the side wall 110ST_SW of the first lower wiring structure 111ST. The first wiring protective film 150_S1 may be in contact with the side wall 110ST_SW of the first lower wiring structure 111ST. For example, the first wiring protective film 150_S1 may extend up to a bottom surface 110ST_BS of the first lower wiring structure 111ST.

The second wiring protective film 150_S2 may extend along a part of the side wall 110ST_SW of the second lower wiring structure 112ST. The second wiring protective film 150_S2 may be in contact with the side wall 110ST_SW of the second lower wiring structure 112ST. For example, the second wiring protective film 150_S2 may extend up to the bottom surface 110ST_BS of the second lower wiring structure 112ST.

In the semiconductor device according to some embodiments, the wiring protective film 150 may include a connection wiring protective film 150_B extending along the bottom surface of the wiring isolation trench 110_T. The connection wiring protective film 150_B may extend along the upper surface of the lower interlayer insulating film 50.

For example, the connection wiring protective film 150_B may connect the first wiring protective film 150_S1 and the second wiring protective film 150_S2. The connection wiring protective film 150_B may be directly connected to the first wiring protective film 150_S1 and the second wiring protective film 150_S2.

The first wiring protective film 150_S1 may include a cover region 150CR_S1 and a plurality of protruding regions 150PR_S1. The cover region 150CR_S1 of the first wiring protective film is directly connected to the plurality of protruding regions 150PR_S1 of the first wiring protective film.

The cover region 150CR_S1 of the first wiring protective film may cover the side wall 110ST_SW of the first lower wiring structure 111ST. The cover region 150CR_S1 of the first wiring protective film may be in contact with the side wall 110ST_SW of the first lower wiring structure 111ST.

From the viewpoint of the cross-sectional view, there may be a cover imaginary line that is drawn to be parallel to the side wall 110ST_SW of the first lower wiring structure 111ST. At this time, the cover region 150CR_S1 of the first wiring protective film may be the first wiring protective film 150_S1 located between the side wall 110ST_SW of the first lower wiring structure 111ST and a cover imaginary line. For example, the cover imaginary line may pass through a point in the first wiring protective film 150_S1 on which the thickness in the first direction DR1 is smallest. For example, the cover region 150CR_S1 of the first wiring protective film extending along the side wall 110ST_SW of the first lower wiring structure 111ST may have a uniform thickness.

The protruding region 150PR_S1 of the first wiring protective film may protrude from the cover region 150CR_S1 of the first wiring protective film in the first direction DR1 toward the second lower wiring structure 112ST. As such, an inner surface of the first wiring protective film 150_S1 may be an uneven surface.

The second wiring protective film 150_S2 may include a cover region 150CR_S2 and a plurality of protruding regions 150PR_S2. The cover region 150CR_S2 of the second wiring protective film is directly connected to the plurality of protruding regions 150PR_S2 of the second wiring protective film.

The cover region 150CR_S2 of the second wiring protective film may cover the side wall 110ST_SW of the second lower wiring structure 112ST. The cover region 150CR_S2 of the second wiring protective film may be in contact with the side wall 110ST_SW of the second lower wiring structure 112ST. For example, the cover region 150CR_S2 of the second wiring protective film extending along the side wall 110ST_SW of the second lower wiring structure 112ST may have a uniform thickness.

As an example, the thickness of the cover region 150CR_S2 of the second wiring protective film may be the same as the thickness of the cover region 150CR_S1 of the first wiring protective film. As another example, the thickness of the cover region 150CR_S2 of the second wiring protective film may be different from the thickness of the cover region 150CR_S1 of the first wiring protective film.

The protruding region 150PR_S2 of the second wiring protective film may protrude from the cover region 150CR_S2 of the second wiring protective film in the first direction DR1 toward the first lower wiring structure 111ST. As such, an inner surface of the first wiring protective film 150_S1 may be an uneven surface.

The connection wiring protective film 150_B may include a cover region 150CR_B and at least one or more protruding regions 150PR_B. The cover region 150CR_B of the connection wiring protective film may extend along the upper surface of the lower interlayer insulating film 50.

The protruding region 150PR_B of the connection wiring protective film may protrude from the cover region 150CR_B of the connection wiring protective film in the third direction DR3. The protruding region 150PR_B of the connection wiring protective film is directly connected to the cover region 150CR_B of the connection wiring protective film. As such, an inner surface of the connection wiring protective film 150_B may be an uneven surface.

The shape of the wiring protective film 150 will be described below in a different manner. The following description will be given using the first wiring protective film 150_S1. It goes without saying that the description of the first wiring protective film 150_S1 may be applied to the second wiring protective film 150_S2.

The first wiring protective film 150_S1 may include a first point PS1, a second point PS2, a third point PS3, and a fourth point PS4. A height H11 from the bottom surface 110ST_BS of the first lower wiring structure 111ST to the first point PS1 is smaller than a height H12 from the bottom surface 110ST_BS of the first lower wiring structure 111ST to the second point PS2. A height H12 from the bottom surface 110ST_BS of the first lower wiring structure 111ST to the second point PS2 is smaller than a height H13 from the bottom surface 110ST_BS of the first lower wiring structure 111ST to the third point PS3. A height H13 from the bottom surface 110ST_BS of the first lower wiring structure 111ST to the third point PS3 is smaller than a height H14 from the bottom surface 110ST_BS of the first lower wiring structure 111ST to the fourth point PS2.

A thickness t11 of the first wiring protective film 150_S1 at the first point PS1 of the first wiring protective film 150_S1 is larger than a thickness t12 of the first wiring protective film 150_S1 at the second point PS2 of the first wiring protective film 150_S1. A thickness t12 of the first wiring protective film 150_S1 at the second point PS2 of the first wiring protective film 150_S1 is smaller than a thickness t13 of the first wiring protective film 150_S1 at the third point PS3 of the first wiring protective film 150_S1. A thickness t13 of the first wiring protective film 150_S1 at the third point PS3 of the first wiring protective film 150_S1 is larger than a thickness t14 of the first wiring protective film 150_S1 at the fourth point PS4 of the first wiring protective film 150_S1.

From the viewpoint of a cross-sectional view, although the uppermost portion of the first wiring protective film 150_S1 and the uppermost portion of the second wiring protective film 150_S2 are shown as being lower than the upper surface 120_US of the lower line wiring on the basis of the bottom surface of the bottom surface 110ST_BS of the lower wiring structure, the embodiment is not limited thereto. Unlike the shown example, as an example, the uppermost portion of the first wiring protective film 150_S1 and the uppermost portion of the second wiring protective film 150_S2 may be placed on the same plane as the upper surface 120_US of the lower wiring. As another example, the uppermost portion of the first wiring protective film 150_S1 and the uppermost portion of the second wiring protective film 150_S2 may be higher than the upper surface 120_US of the lower line wiring.

The wiring protective film 150 may include an insulating material including silicon (Si) and oxygen (O). In the semiconductor device according to some embodiments, the wiring protective film 150 may further include at least one of carbon (C), nitrogen (N) or hydrogen (H). For example, the wiring protective film 150 may include, but is not limited to, one of silicon oxide (SiO), silicon oxynitride (SiON), silicon oxycarbide (SiCO) or silicon carbon oxyhydride (SiCOH).

The liner capping film 140 may be disposed on the wiring protective film 150. The liner capping layer 140 may be disposed between the lower wiring structures 110ST that are adjacent to each other in the first direction DR1.

The liner capping film 140 may be in contact with the wiring protective film 150. The liner capping film 140 may be in contact with the uppermost portion of the wiring protective film 150.

The liner capping film 140 may be in contact with the lower wiring structure 110ST. For example, the liner capping film 140 may be in contact with the side wall(s) 110ST_SW of the lower wiring structure.

The liner capping film 140 may be in contact with the upper portion 110ST_UP of the lower wiring structure. For example, the liner capping film 140 may be in contact with the side wall 110ST_SW of the upper portion 110ST_UP of the lower wiring structure.

The liner capping film 140 may extend along the side wall 110ST_SW of the lower wiring structure. For example, the liner capping film 140 may be in contact with the remainder of the side wall 110ST_SW of the lower wiring structure. The liner capping film 140 may extend up to the upper surface 110ST_US of the lower wiring structure.

The liner capping films 140 disposed on the side walls 110ST_SW of the lower wiring structure adjacent in the first direction DR1 are connected to each other. For example, from the viewpoint of a cross-sectional view, the liner capping film 140 may have a “U” shape.

The liner capping film 140 may extend along the side walls 110ST_SW of the first lower wiring structure 111ST and the side walls 110ST_SW of the second lower wiring structure 112ST. The liner capping film 140 may include a connection portion that connects the side walls 110ST_SW of the first lower wiring structure 111ST and the side walls 110ST_SW of the second lower wiring structure 112ST.

In one embodiment, the upper surface 120_US of the lower line wiring 120 may be positioned higher than a bottom surface of the liner capping film 140, to form a stepped portion therebetween, but the embodiment is not limited thereto.

The liner capping film 140 may include one of silicon oxide, silicon nitride or silicon oxynitride. In the semiconductor device according to some embodiments, the liner capping film 140 may include silicon oxide.

The filling capping film 145 may be disposed on the liner capping film 140. The filling capping film 145 may be disposed between the lower wiring structures 110ST that are adjacent to each other in the first direction DR1.

The upper surface of the filling capping film 145 may be placed in the same plane as the upper surface 110ST_US of the lower wiring structure, but the embodiment is not limited thereto.

The filling capping film 145 may include an insulating material including silicon (Si) and oxygen (O). The filling capping film 145 may further include at least one of carbon (C), nitrogen (N) or hydrogen (H). The filling capping film 145 includes the same material as the wiring protective film 150.

A wiring air gap 110_AG may be disposed between the lower wiring structures 110ST that are adjacent to each other in the first direction DR1. The wiring air gap 110_AG may be disposed between the first lower wiring structure 111ST and the second lower wiring structure 112ST.

The wiring air gap 110_AG may be disposed between the wiring protective film 150 and the liner capping film 140. In the semiconductor device according to some embodiments, the wiring air gap 110_AG may be surrounded by the wiring protective film 150 and the liner capping film 140 from the viewpoint of a cross-sectional view.

The liner capping film 140 and the filling capping film 145 may be disposed on the wiring protective film 150 and the wiring air gap 110_AG.

From the viewpoint of a cross-sectional view, the wiring protective film 150 may include an outer side face that is in contact with the lower wiring structure 110ST, and an inner side face that encloses the wiring air gap 110_AG. The inner side face of the wiring protective film 150 may be defined by the protruding region 150PR_S1 of the first wiring protective film, the protruding region 150PR_S2 of the second wiring protective film, and the protruding region 150PR_B of the connection wiring protective film. The inner side face of the wiring protective film 150 may include irregularities due to the protruding regions 150PR_S1, 150PR_S2, and 150PR_B. The irregularities formed on the inner side face of the wiring protective film 150 may lengthen a path of leakage current between adjacent lower wiring structures 110ST. In other words, the irregularities formed on the inner side face of the wiring protective film 150 may reduce the leakage current between adjacent lower wiring structures 110ST. Accordingly, the performance and reliability of the semiconductor device can be improved.

The upper wiring structure 210ST may be disposed at a second metal level different from the first metal level. The upper wiring structure 210ST may be disposed in a second metal level higher than the first metal level.

The upper wiring structure 210ST disposed at the second metal level may be connected to the lower wiring structure 110ST disposed at the first metal level.

For example, the upper wiring structure 210ST may include an upper line wiring 220 and an upper wiring insulation capping film 230.

The upper line wiring 220 may extend long in the first direction DR1. The upper line wiring 220 may include a line portion extending in the first direction DR1, and a via portion connected to the lower wiring structure 110ST. The via portion of the upper line wiring 220 may protrude from the line portion of the upper line wiring 220 in the third direction DR3.

For example, the upper line wiring 220 may have an integrated structure, but the embodiment is not limited thereto.

The upper wiring insulation capping film 230 may be disposed on the upper line wiring 220. The upper wiring insulation capping film 230 may extend along the upper surface of the upper line wiring 220.

The upper line wiring 220 may include at least one of ruthenium (Ru), rhodium (Rh), iridium (Ir), molybdenum (Mo), tungsten (W), RuAl, NiAl, NbB₂, MoB₂, TaB₂, V₂AlC or CrAlC. The upper wiring insulation capping film 230 may include at least one of silicon oxide, silicon nitride, silicon oxynitride or silicon carbonitride.

The upper interlayer insulating film 190 may be disposed on the lower wiring structure 110ST and the filling capping film 145. The upper interlayer insulating film 190 may enclose the upper wiring structure 210ST.

The upper interlayer insulating film 190 may include, for example, at least one of silicon oxide, silicon nitride, silicon oxynitride, and a low dielectric constant material.

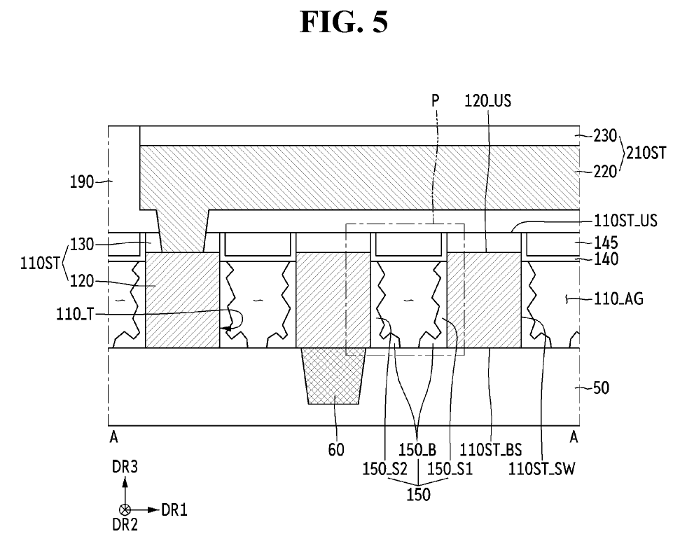

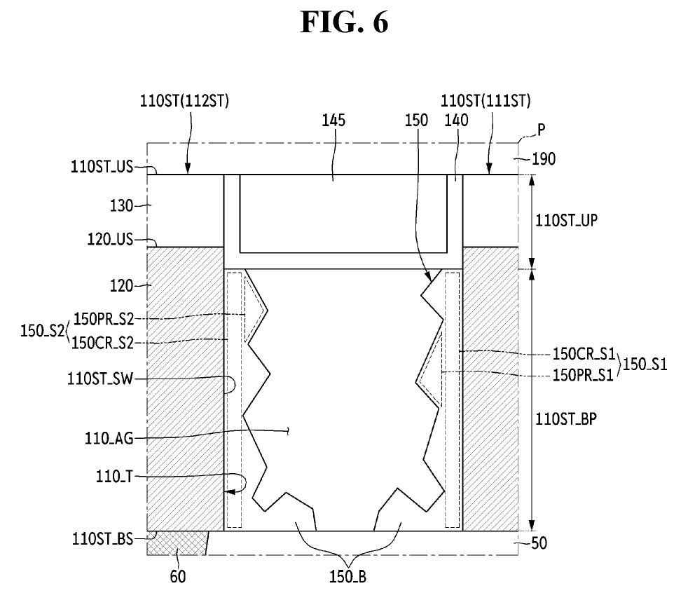

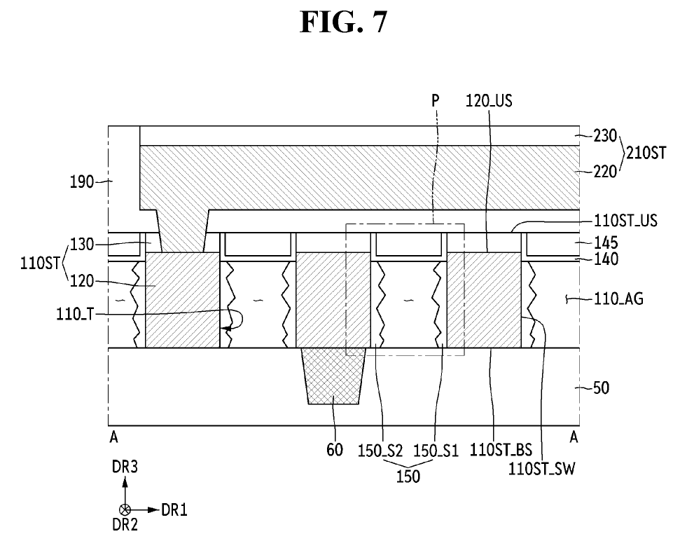

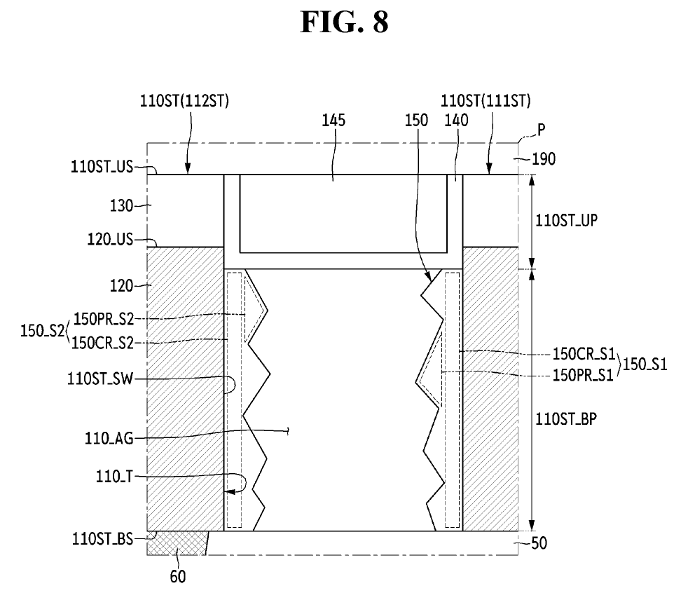

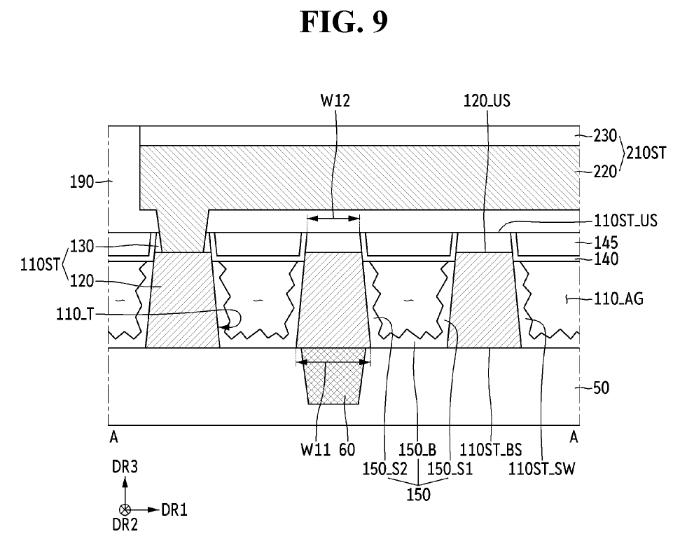

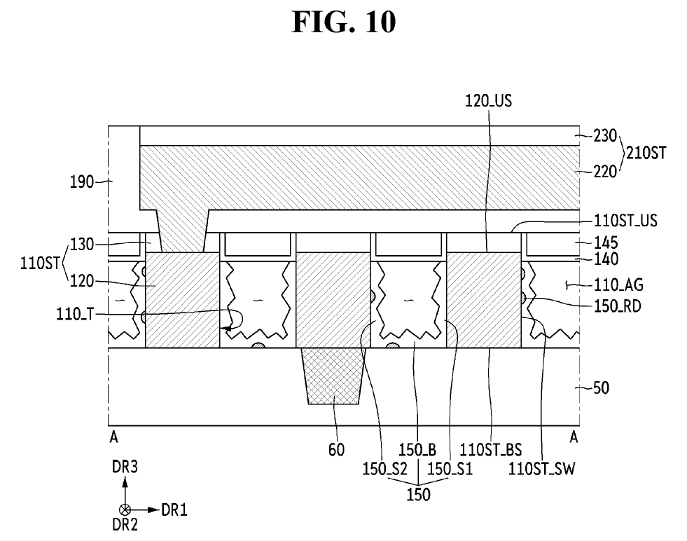

FIGS. 5 and 6 are diagrams for explaining a semiconductor device according to some embodiments. FIGS. 7 and 8 are diagrams for explaining the semiconductor device according to some embodiments. FIGS. 9 and 10 are diagrams for explaining the semiconductor device according to some embodiments. For convenience of explanation, differences from those described using FIGS. 1-4 will be mainly described.

With reference to FIGS. 5-8, in the semiconductor device according to some embodiments, the wiring protective film 150 between the lower wiring structures 110ST adjacent in the first direction DR1 may be separated into two portions.

The wiring protective film 150 that is in contact with the first lower wiring structure 111ST is not in contact with the wiring protective film 150 that is in contact with the second lower wiring structure 112ST.

In FIGS. 5 and 6, the wiring protective film 150 between the lower wiring structures 110ST adjacent in the first direction DR1 may have an “L” shape.

The wiring protective film 150 may include a first wiring protective film 150_S1, a second wiring protective film 150_S2, and a connection wiring protective film 150_B separated into two portions. Each of the connection wiring protective films 150_B separated into two portions may extend or protrude from the first wiring protective film 150_S1 and the second wiring protective film 150_S2 in the first direction DR1.

From the viewpoint of a cross-sectional view, a part of the upper surface of the lower interlayer insulating film 50 may be exposed. The wiring air gap 110_AG may be surrounded by the wiring protective film 150, the liner capping film 140, and the lower interlayer insulating film 50.

In FIGS. 7 and 8, the wiring protective film 150 does not include the connection wiring protective film (150_B of FIG. 3).

With reference to FIG. 9, in the semiconductor device according to some embodiments, a width W11 in the first direction DR1 of the bottom surface 110ST_BS of the lower wiring structure may be different from a width W12 in the first direction DR1 of the upper surface 110ST_US of the lower wiring structure.

The width W11 of the bottom surface 110ST_BS of the lower wiring structure in the first direction DR1 may be greater than the width W12 of the upper surface 110ST_US of the lower wiring structure in the first direction DR1.

Referring to FIG. 10, the semiconductor device according to some embodiments may further include a sacrificial material residue 150_RD disposed between the wiring protective film 150 and the lower wiring structure 110ST.

The sacrificial material residue 150_RD may be disposed on the side wall 110ST_SW of the lower wiring structure and/or the upper surface of the lower interlayer insulating film 50. The sacrificial material residue 150_RD may be a sacrificial material film 110SC that remains without being removed in the process of forming the wiring air gap 110_AG.

The sacrificial material residue 150_RD may include a polymer including carbon (C) and hydrogen (H). For example, the sacrificial material residue 150_RD may further include at least one of oxygen (O) or nitrogen (N).

When the sacrificial material residue 150_RD is present on the side wall 110ST_SW of the lower wiring structure, the thickness of the first wiring protective film 150_S1 in FIG. 4 may be measured on the basis of the side wall of the side wall 110ST_SW of the lower wiring structure.

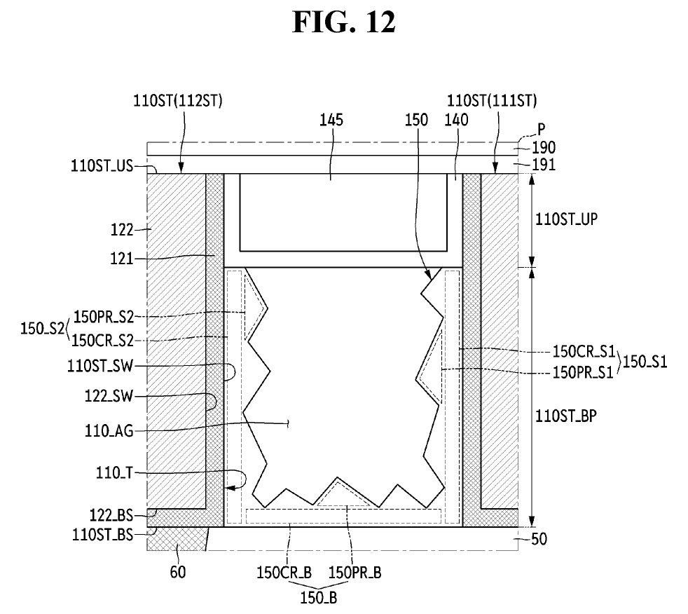

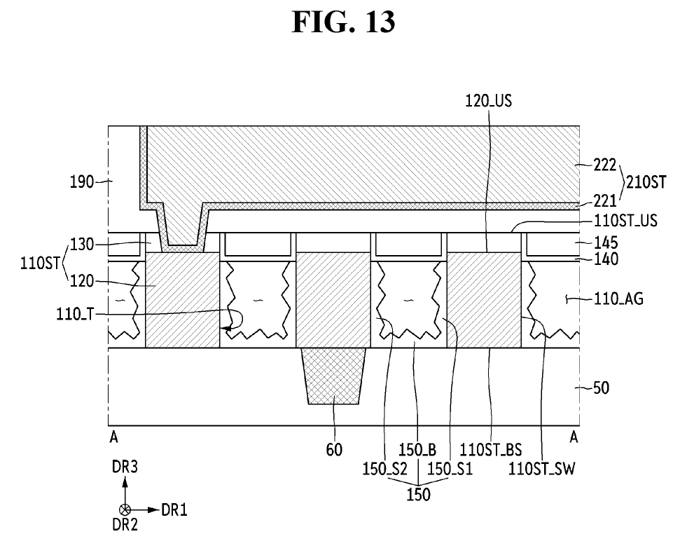

FIGS. 11 and 12 are diagrams for explaining a semiconductor device according to some embodiments. FIG. 13 is a diagram for explaining a semiconductor device according to some embodiments. For convenience of explanation, differences from those described using FIGS. 1-4 will be mainly described.

Referring to FIGS. 11 and 12, in the semiconductor device according to some embodiments, the lower wiring structure 110ST may include a lower wiring barrier film 121 and a lower wiring filling film 122.

The lower wiring filling film 122 may be disposed on the lower wiring barrier film 121. The lower wiring barrier film 121 may extend along the side wall 122_SW of the lower wiring filling film and the bottom surface 122_BS of the lower wiring filling film.

The side wall 110ST_SW of the lower wiring structure and the bottom surface 110ST_BS of the lower wiring structure may be defined by the lower wiring barrier film 121. The upper surface 110ST_US of the lower wiring structure may be defined by the lower wiring barrier film 121 and the lower wiring filling film 122.

As an example, the width W11 of the bottom surface 110ST_BS of the lower wiring structure in the first direction DR1 may be the same as the width W12 of the upper surface 110ST_US of the lower wiring structure in the first direction DR1. As another example, the width W11 of the bottom surface 110ST_BS of the lower wiring structure in the first direction DR1 may be smaller than the width W12 of the upper surface 110ST_US of the lower wiring structure in the first direction DR1.

The lower wiring barrier film 121 may include at least one of a metal, a conductive metal nitride, a conductive metal carbide, a conductive metal oxide, a conductive metal carbonitride, a conductive metal oxynitride or a two-dimensional material (2D material). The lower wiring barrier film 121 may include, but is not limited to, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), molybdenum (Mo), and a two-dimensional material. The lower wiring barrier film 121 is shown as being a single film, but is not limited thereto.

The lower wiring filling film 122 may include a metal. The lower wiring filling film 122 may include, for example, at least one of aluminum (Al), copper (Cu), tungsten (W), or cobalt (Co).

The two-dimensional material (2D material) may include a 2D allotrope or a 2D compound, and may include, for example, but is not limited to, at least one of graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of the present disclosure are not limited by the above-mentioned materials.

An etching stop film 191 extends along the upper surface 110ST_US of the lower wiring structure and the upper surface of the filling capping film 145. The etching stop film 191 may include at least one of silicon nitride, silicon carbonitride, silicon oxycarbide, silicon oxynitride, silicon oxide or silicon oxycarbonitride.

The upper wiring structure 210ST may penetrate the etching stop film 191, and be connected to the lower wiring structure 110ST.

Referring to FIG. 13, in the semiconductor device according to some embodiments, the upper wiring structure 210ST may include an upper wiring barrier film 221 and an upper wiring filling film 222.

The upper wiring filling film 222 may be disposed on the upper wiring barrier film 221. The upper wiring barrier film 221 may extend along the side walls of the upper wiring filling film 222 and the bottom surface of the upper wiring filling film 222.

The material included in the upper wiring barrier film 221 may be substantially the same as the description for the lower wiring barrier film 121. The material included in the upper wiring filling film 222 may be substantially the same as description for the lower wiring filling film 122.

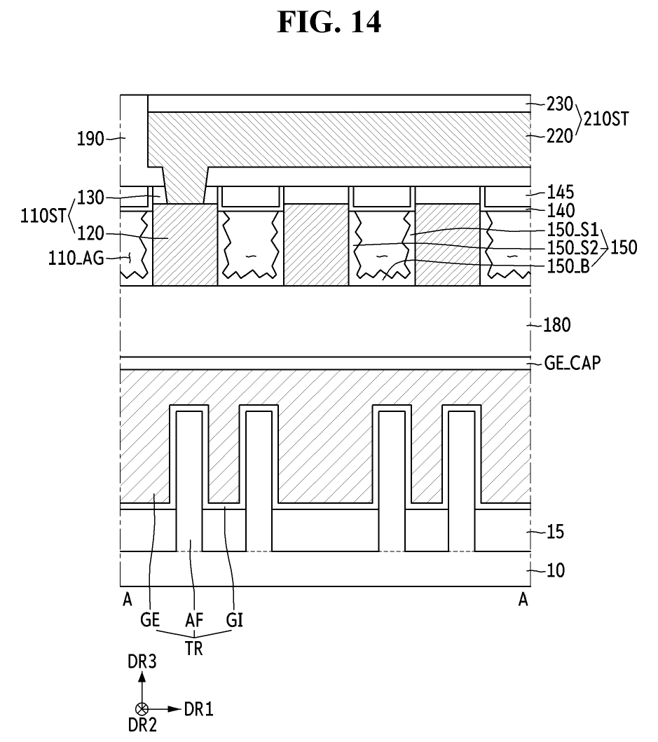

FIG. 14 is a diagram for explaining a semiconductor device according to some embodiments. For convenience of explanation, differences from those described using FIGS. 1-4 will be mainly described.

For reference, FIG. 14 shows an example diagram taken along a first gate electrode GE.

In FIG. 14, the fin-shaped pattern AF is shown to extend in the second direction DR2, and the first gate electrode GE is shown to extend in the first direction DR1, but the embodiment is not limited thereto.

Referring to FIG. 14, the semiconductor device according to some embodiments may include a transistor TR disposed between the substrate 10 and the lower wiring structure 110ST.

The substrate 10 may be a silicon substrate or silicon-on-insulator (SOI). In contrast, the substrate 10 may include, but is not limited to, silicon germanium, silicon germanium on insulator (SGOI), indium antimonide, lead telluride, indium arsenide, indium phosphide, gallium arsenide or gallium antimonide.

The transistor TR includes a fin-shaped pattern AF, a first gate electrode GE on the fin-shaped pattern AF, and a first gate insulating film GI between the fin-shaped pattern AF and the first gate electrode GE.

Although not shown, the transistor TR may include source/drain patterns disposed on both sides of the first gate electrode GE.

The fin-shaped pattern AF may protrude from the substrate 10. The fin-shaped pattern AF may extend long in the second direction DR2. The fin-shaped pattern AF may be a part of the substrate 10, and may include an epitaxial layer grown from the substrate 10. The fin-shaped pattern AF may include, for example, silicon or germanium which are elemental semiconductor materials. Also, the fin-shaped pattern AF may include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element. The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

A field insulating film 15 may be formed on the substrate 10. The field insulating film 15 may be formed on a part of side walls of the fin-shaped pattern AF. The fin-shaped pattern AF may protrude upward from the upper surface of the field insulating film 15. The field insulating film 15 may include, for example, an oxide film, a nitride film, an oxynitride film or a combination thereof.

The first gate electrode GE may be disposed on the fin-shaped pattern AF. The first gate electrode GE may extend in the first direction DR1. The first gate electrode GE may intersect the fin-shaped pattern AF.

The first gate electrode GE may include, for example, at least one of metal, conductive metal nitride, conductive metal carbonitride, conductive metal carbide, metal silicide, doped semiconductor material, conductive metal oxynitride, and conductive metal oxide.

The first gate insulating film GI may be disposed between the first gate electrode GE and the fin-shaped pattern AF, and between the first gate electrode GE and the field insulating film 15. The first gate insulating film GI may include, for example, silicon oxide, silicon oxynitride, silicon nitride or a high dielectric constant material having a dielectric constant greater than that of silicon oxide. The high dielectric constant material may include, for example, at least one of boron nitride, metal oxide or metal silicon oxide.

The semiconductor device according to some embodiments may include a NC (Negative Capacitance) FET that uses a negative capacitor. For example, the first gate insulating film GI may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) under 60 mV/decade at a room temperature.

The ferroelectric material film may have ferroelectric properties. The ferroelectric material film may include, for example, at least one of hafnium oxide, hafnium zirconium oxide, barium strontium titanium oxide, barium titanium oxide or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al) or yttrium (Y).

When the dopant is aluminum (Al), the ferroelectric material film may include 3 to 8 at% (atomic %) aluminum. Here, a ratio of the dopant may be a ratio of aluminum to the sum of hafnium and aluminum.

When the dopant is silicon (Si), the ferroelectric material film may include 2 to 10 at% silicon. When the dopant is yttrium (Y), the ferroelectric material film may include 2 to 10 at% yttrium. When the dopant is gadolinium (Gd), the ferroelectric material film may include 1 to 7 at% gadolinium. When the dopant is zirconium (Zr), the ferroelectric material film may include 50 to 80 at% zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide or aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. A thickness of the ferroelectric material film may be, for example, but is not limited to, 0.5 to 10 nm. Since a critical thickness that exhibits the ferroelectric properties may vary for each ferroelectric material, the thickness of the ferroelectric material film may vary depending on the ferroelectric material.

As an example, the first gate insulating film GI may include a single ferroelectric material film. As another example, the first gate insulating film GI may include a plurality of ferroelectric material films spaced apart from each other. The first gate insulating film GI may have a stacked film structure in which the plurality of ferroelectric material films and the plurality of paraelectric material films are stacked alternately.

A gate capping pattern GE_CAP may be disposed on the first gate electrode GE. The lower wiring structure 110ST may be disposed on the first gate electrode GE. The lower wiring structure 110ST is shown as not being connected to the first gate electrode GE, but is not limited thereto.

The first interlayer insulating film 180 may be disposed on the gate capping pattern GE_CAP. The first interlayer insulating film 180 may include, for example, at least one of silicon oxide, silicon nitride, silicon oxynitride or a low dielectric constant material.

The lower wiring structure 110ST may be disposed in the first interlayer insulating film 180. As an example, the first interlayer insulating film 180 may correspond to the lower interlayer insulating film 50 of FIG. 2. Although not shown, a lower conductive pattern (60 of FIG. 2) may be disposed inside the first interlayer insulating film 180.

As another example, the first interlayer insulating film 180 and the gate capping pattern GE_CAP may correspond to the lower interlayer insulating film 50 of FIG. 2. Although not shown, the lower conductive pattern (60 of FIG. 2) may be disposed inside the first interlayer insulating film 180 and the gate capping pattern GE_CAP.

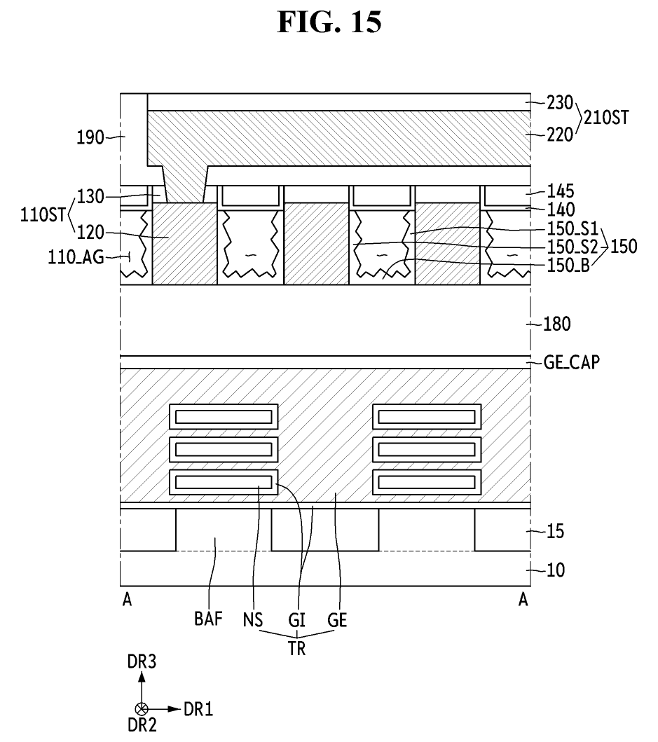

FIG. 15 is a diagram for explaining a semiconductor device according to some embodiments. For convenience of explanation, differences from those described using FIGS. 14 will be mainly described.

With reference to FIG. 15, in the semiconductor device according to some embodiments, the transistor TR may include a nanosheet NS, a first gate electrode GE that encloses the nanosheet NS, and a first gate insulating film GI between the nanosheet NS and the first gate electrode GE.

The nanosheet NS may be disposed on the lower fin-shaped pattern BAF. The nanosheet NS may be spaced apart from the lower fin-shaped pattern BAF in the third direction DR3. The transistor TR is shown to include three nanosheets NS spaced apart in the third direction DR3, but the embodiment is not limited thereto. It goes without saying that the number of nanosheets NS disposed on the lower fin-shaped pattern BAF in the third direction DR3 may be larger or smaller than three.

Each of the lower fin-shaped pattern BAF and the nanosheet NS may include, for example, silicon or germanium, which is an elemental semiconductor material. Each of the lower fin-shaped pattern BAF and the nanosheet NS may include a compound semiconductor, and may include, for example, a group IV-IV compound semiconductor or a group III-V compound semiconductor. The lower fin-shaped pattern BAF and the nanosheet NS may include the same material or different materials.

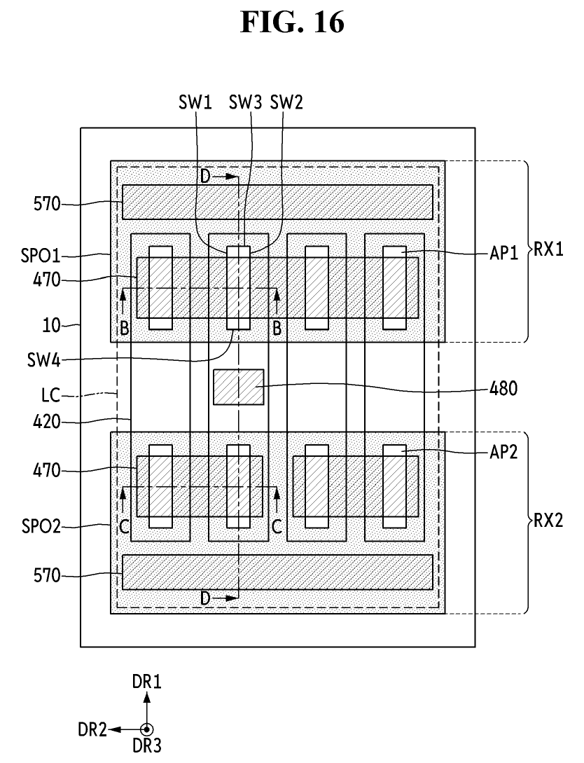

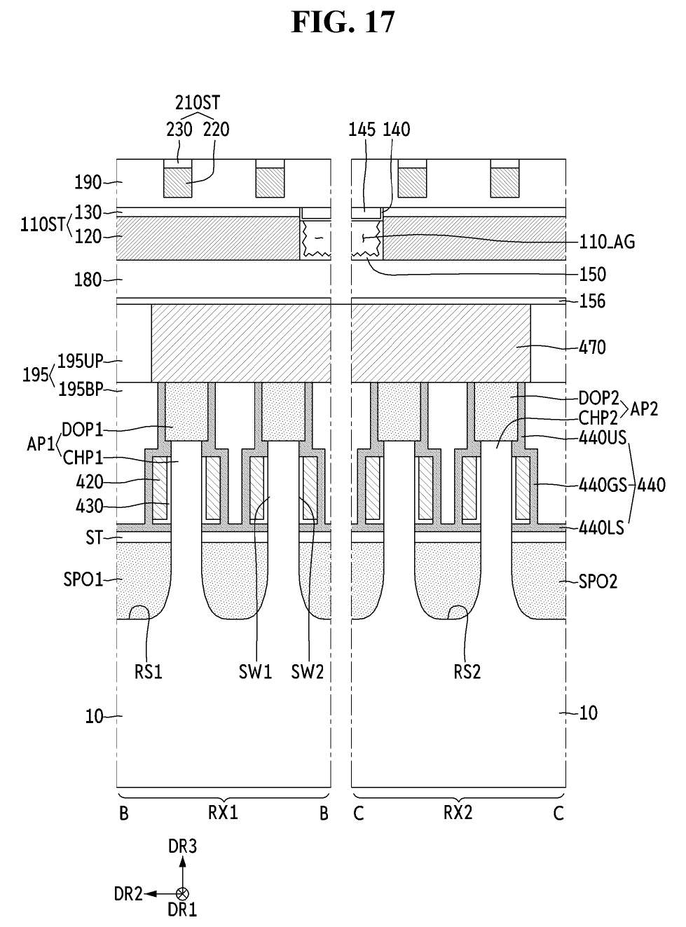

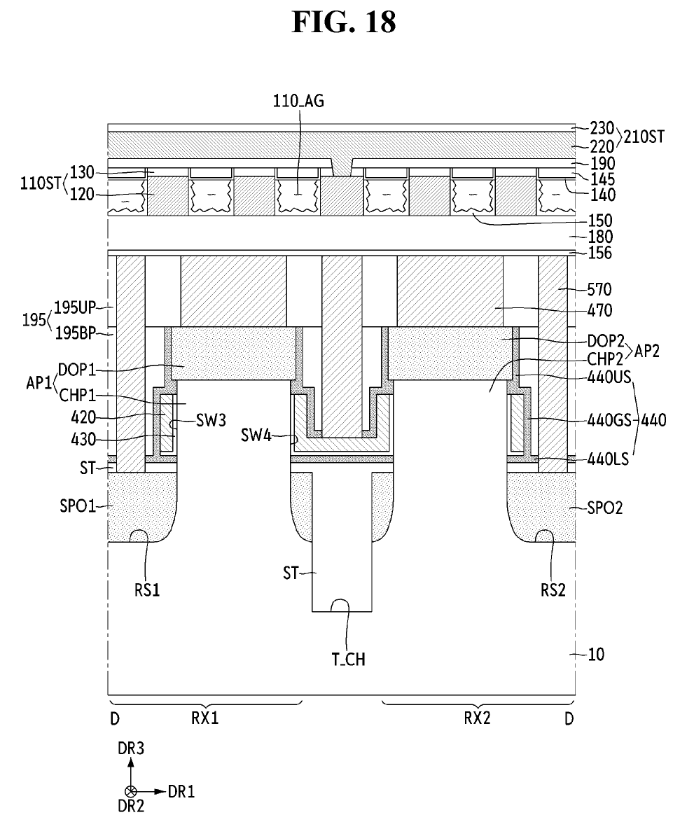

FIGS. 16-18 are diagrams for explaining a semiconductor device according to some embodiments. For reference, FIG. 16 is a plan view for explaining the semiconductor device according to some embodiments. FIG. 17 is a cross-sectional view taken along lines B-B and C-C of FIG. 16. FIG. 18 is a cross-sectional view taken along line D-D of FIG. 16.

With reference to FIGS. 16-18, a logic cell LC may be provided on the substrate 10. The logic cell LC may mean a logic element (e.g., an inverter, a flip-flop, etc.) that performs a specific function. The logic cell LC may include vertical transistors (vertical FETs) that constitute the logic element, and wirings that connect the vertical transistors to each other.

The logic cell LC on the substrate 10 may include a first active region RX1 and a second active region RX2. For example, the first active region RX1 may be a PMOSFET region, and the second active region RX2 may be an NMOSFET region. The first and second active regions RX1 and RX2 may be defined by a trench T_CH formed in the upper portion of the substrate 10. The first and second active regions RX1 and RX2 may be spaced apart from each other in the first direction DR1.

A first lower epitaxial pattern SPO1 may be provided on the first active region RX1, and a second lower epitaxial pattern SPO2 may be provided on the second active region RX2. From the viewpoint of a plan view, the first lower epitaxial pattern SPO1 may overlap the first active region RX1, and the second lower epitaxial pattern SPO2 may overlap the second active region RX2. The first and second lower epitaxial patterns SPO1 and SPO2 may be epitaxial patterns formed by a selective epitaxial growth process. The first lower epitaxial pattern SPO1 may be provided inside a first recess region RS1 of the substrate 10, and the second lower epitaxial pattern SPO2 may be provided inside a second recess region RS2 of the substrate 10.

First active patterns AP1 may be provided on the first active region RX1, and second active patterns AP2 may be provided on the second active region RX2. Each of the first and second active patterns AP1 and AP2 may have a fin shape protruding vertically. From the viewpoint of a plan view, each of the first and second active patterns AP1 and AP2 may have a bar shape extending in the first direction DR1. The first active patterns AP1 may be arranged along the second direction DR2, and the second active patterns AP2 may be arranged along the second direction DR2.

Each of the first active patterns AP1 may include a first channel pattern CHP1 protruding vertically from the first lower epitaxial pattern SPO1, and a first upper epitaxial pattern DOP1 on the first channel pattern CHP1. Each of the second active patterns AP2 may include a second channel pattern CHP2 protruding vertically from the second lower epitaxial pattern SPO2, and a second upper epitaxial pattern DOP2 on the second channel pattern CHP2.

An element isolation film ST may be provided on the substrate 10 to fill the trench T_CH. The element isolation film ST may cover the upper surfaces of the first and second lower epitaxial patterns SPO1 and SPO2. The first and second active patterns AP1 and AP2 may protrude vertically above the element isolation film ST.

A plurality of second gate electrodes 420 extending parallel to each other in the first direction DR1 may be provided on the element isolation film ST. The second gate electrodes 420 may be arranged along the second direction DR2. The second gate electrodes 420 may enclose the first channel pattern CHP1 of the first active pattern AP1, and may enclose the second channel pattern CHP2 of the second active pattern AP2. For example, the first channel pattern CHP1 of the first active pattern AP1 may have first to fourth side walls SW1 to SW4. The first and second side walls SW1 and SW2 may be opposite to each other in the second direction DR2, and the third and fourth side walls SW3 and SW4 may be opposite to each other in the first direction DR1. The second gate electrode 420 may be provided on the first to fourth side walls SW1 to SW4. In other words, the second gate electrode 420 may surround the first to fourth side walls SW1 to SW4.

A second gate insulating film 430 may be interposed between the second gate electrode 420 and each of the first and second channel patterns CHP1 and CHP2. The second gate insulating film 430 may cover a bottom surface of the second gate electrode 420 and an inner side wall of the second gate electrode 420. For example, the second gate insulating film 430 may directly cover the first to fourth side walls SW1 to SW4 of the first active pattern AP1.

The first and second upper epitaxial patterns DOP1 and DOP2 protrude vertically above the second gate electrode 420. The upper surface of the second gate electrode 420 may be lower than the bottom surfaces of each of the first and second upper epitaxial patterns DOP1 and DOP2. In other words, each of the first and second active patterns AP1 and AP2 may have a structure that protrudes vertically from the substrate 10 and penetrates the second gate electrode 420.

The semiconductor device according to some embodiments may include vertical transistors in which carriers move in the third direction DR3. For example, when a voltage is applied to the second gate electrode 420 and the transistor is turned “on”, carriers may move from the lower epitaxial patterns SOP1 and SOP2 to the upper epitaxial patterns DOP1 and DOP2 through the channel patterns CHP1 and CHP2. In the semiconductor device according to some embodiments, the second gate electrode 420 may completely surround the side walls SW1 to SW4 of the channel patterns CHP1 and CHP2. The transistor according to the present disclosure may be a three-dimensional field effect transistor (e.g., VFET) having a gate-all-around structure. Because the gate surrounds the channel, the semiconductor device according to some embodiments may have excellent electrical characteristics.

A spacer 440 that covers the second gate electrodes 420 and the first and second active patterns AP1 and AP2 may be provided on the element isolation film ST. The spacer 440 may include silicon nitride or silicon oxynitride. The spacer 440 may include a lower spacer 440LS, an upper spacer 440US, and a gate spacer 440GS between the lower and upper spacers 440LS and 440US.

The lower spacer 440LS may directly cover the upper surface of the element isolation film ST. The lower spacer 440LS may separate the second gate electrodes 420 from the element isolation film ST in the third direction DR3. The gate spacer 440GS may cover the upper surfaces and outer side walls of each of the second gate electrodes 420. The upper spacer 440 may cover the first and second upper epitaxial patterns DOP1 and DOP2. However, the upper spacer 440US may not cover the upper surfaces of the first and second upper epitaxial patterns DOP1 and DOP2, and may expose the upper surfaces of the first and second upper epitaxial patterns DOP1 and DOP2.

The first portion 195BP of the second interlayer insulating film may be provided on the spacer 440. The upper surface of the first portion 195BP of the second interlayer insulating film may be substantially coplanar with the upper surfaces of the first and second upper epitaxial patterns DOP1 and DOP2. The second portion 195UP of the second interlayer insulating film and the first interlayer insulating film 180 may be sequentially stacked on the first portion 195BP of the second interlayer insulating film. The first portion 195BP of the second interlayer insulating film and the second portion 195UP of the second interlayer insulating film may be included in the second interlayer insulating film 195. The second portion 195UP of the second interlayer insulating film may cover the upper surfaces of the first and second upper epitaxial patterns DOP1 and DOP2.

At least one first source/drain contact 470 which penetrates the second portion 195UP of the second interlayer insulating film and is connected to the first and second upper epitaxial patterns DOP1 and DOP2 may be provided. At least one second source/drain contact 570 which penetrates the second interlayer insulating film 195, the lower spacer 440LS, and the element isolation film ST and is connected to the first and second lower epitaxial patterns SPO1 and SPO2 may be provided. A gate contact 480 which sequentially penetrates the second portion 195UP of the second interlayer insulating film, the first portion 195BP of the second interlayer insulating film, and the gate spacer 440GS and is connected to the second gate electrode 420 may be provided.

A lower etching stop film 156 may be further disposed between the second portion 195UP of the second interlayer insulating film and the first interlayer insulating film 180.

The lower wiring structure 110ST may be disposed in the first interlayer insulating film 180. The detailed description of the lower wiring structure 110ST, the upper wiring structure 210ST, the liner capping film 140, the filling capping film 145, and the wiring protective film 150 may be substantially the same as those described above referring to FIGS. 1-13.

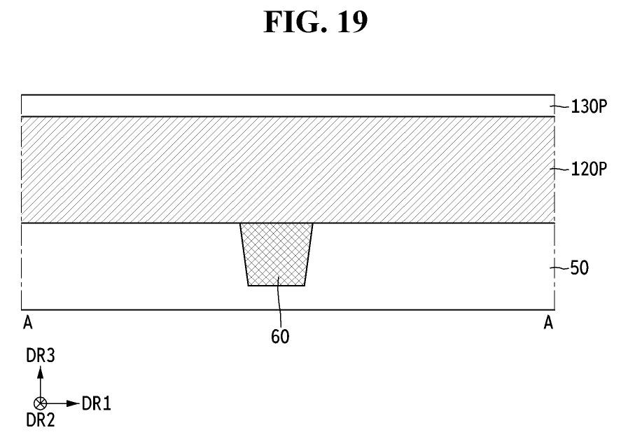

FIGS. 19-25 are intermediate stage diagrams for explaining a method for fabricating a semiconductor device according to some embodiments.

Referring to FIG. 19, a lower conductive pattern 60 may be formed inside the lower interlayer insulating film 50.

Next, a metal material film 120P and a capping film 130P may be sequentially formed on the lower interlayer insulating film 50 and the lower conductive pattern 60.

Unlike the shown example, the lower interlayer insulating film 50 may be disposed on a substrate (10 of FIGS. 14, 15, 17 and 18).

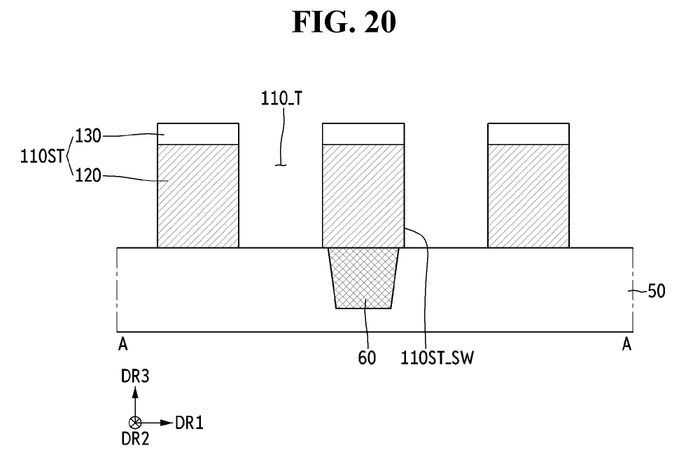

Referring to FIG. 20, the metal material film 120P and the capping film 130P may be patterned through an etching process.

More specifically, an etching mask may be formed on the capping film 130P. Some of the metal material film 120P and the capping film 130P may be removed, using the etching mask. Next, the etching mask may be removed.

A plurality of lower wiring structures 110ST may be formed on the lower interlayer insulating film 50, accordingly. Each lower wiring structures 110ST may include a lower line wiring 120 and a lower wiring insulation capping film 130.

The lower wiring structures 110ST may be separated in the first direction DR1 by the wiring isolation trench 110_T.

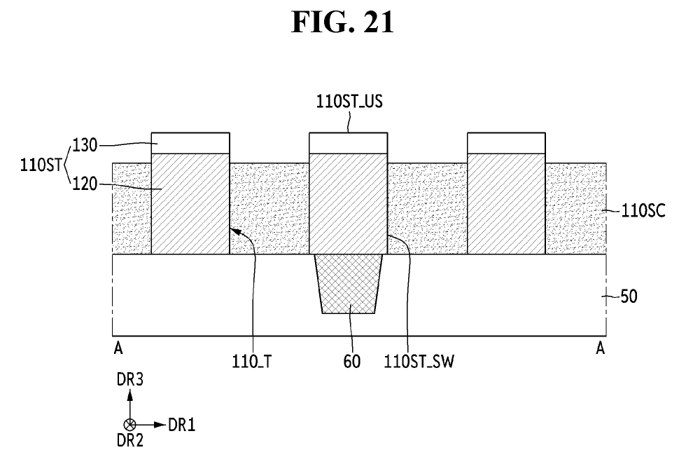

Referring to FIG. 21, a sacrificial material film 110SC may be formed between the lower wiring structures 110ST adjacent to each other in the first direction DR1.

The sacrificial material film 110SC may be formed on the lower interlayer insulating film 50 and the lower conductive pattern 60. The sacrificial material film 110SC may fill a part of the wiring isolation trench 110_T.

The sacrificial material film 110SC may cover a part of the side wall 110ST_SW of the lower wiring structure. The sacrificial material film 110SC is not formed on the upper surface 110ST_US of the lower wiring structure. The sacrificial material film 110SC does not cover the upper surface 110ST_US of the lower wiring structure.

The sacrificial material film 110SC may include a polymer containing carbon (C) and hydrogen (H). For example, the sacrificial material film 110SC may further include at least one of oxygen (O) or nitrogen (N) in the polymer containing carbon (C) and hydrogen (H).

The sacrificial material film 110SC may be formed through a deposition process or a coating process. As an example, when heat of 150°C or more is applied to the sacrificial material film 110SC, the sacrificial material film 110SC may have a property of being decomposed into a monomer. As another example, when the sacrificial material film 110SC is irradiated with ultraviolet (UV), the sacrificial material film 110SC may have a property of being decomposed into a monomer.

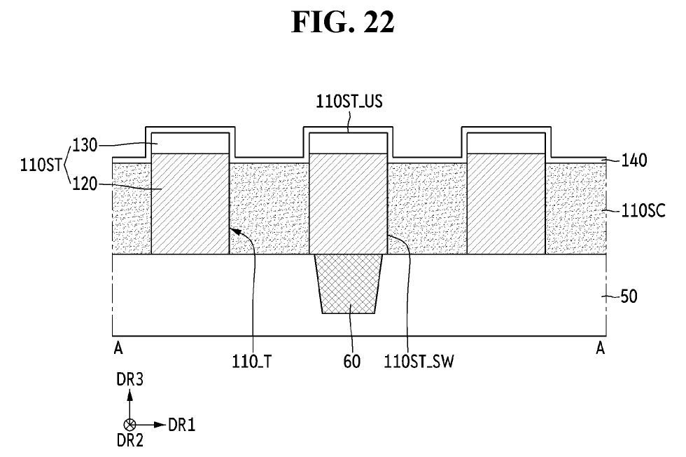

Referring to FIG. 22, a liner capping film 140 may be formed on the sacrificial material film 110SC and the lower wiring structure 110ST.

The liner capping film 140 may extend along the upper surface 110ST_US of the lower wiring structure, and the upper surface of the sacrificial material film 110SC. The liner capping film 140 may extend along the remainder of the side wall 110ST_SW of the lower wiring structure. The remainder of the side wall 110ST_SW of the lower wiring structure may be the side wall of the lower wiring structure 110ST that protrudes beyond the upper surface of the sacrificial material film 110SC.

For example, the liner capping film 140 may be formed using an atomic layer deposition (ALD) method. Although not shown, pin holes may be formed in the liner capping film 140 during the formation of the liner capping film 140.

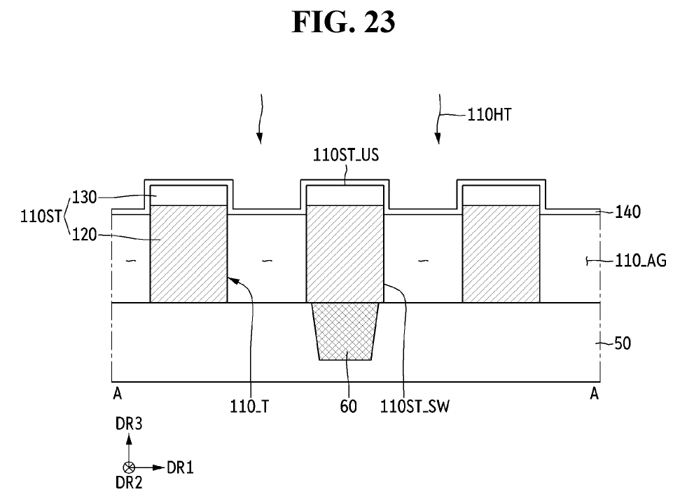

Referring to FIGS. 22 and 23, the sacrificial material film 110SC may be removed using a post-treatment process 110HT.

As a result, the wiring air gap 110_AG may be formed between the lower wiring structures 110ST adjacent to each other in the first direction DR1.

As an example, the post-treatment process 110HT may include a heat treatment process. As another example, the post-treatment process 110HT may include an ultraviolet irradiation process. While the post-treatment process 110HT is performed, the sacrificial material film 110SC is decomposed into monomers and discharged through pinholes included in the liner capping film 140.

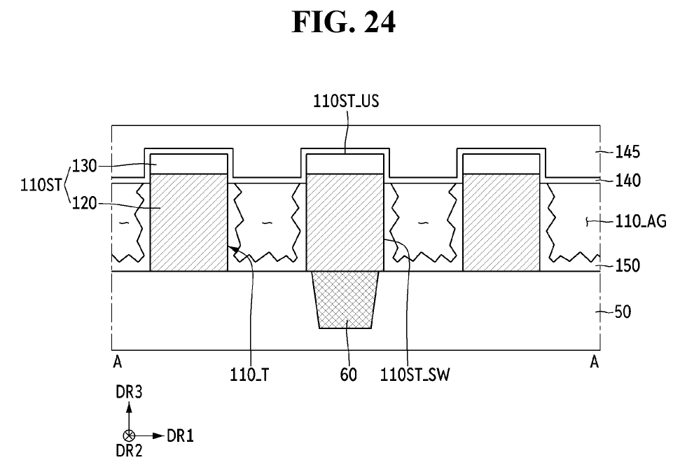

Referring to FIG. 24, a flowable insulating material may be deposited on the liner capping film 140, and a filling capping film 145 may be formed on the liner capping film 140.

During the formation of the filling capping film 145, some of the flowable insulating material may pass through pinholes included in the liner capping film 140. That is, the flowable insulating material may diffuse into the wiring air gap 110_AG through pinholes included in the liner capping film 140.

The flowable insulating material that passes through the pinholes included in the liner capping film 140 may be deposited on the side wall 110ST_SW of the lower wiring structure. Accordingly, a wiring protection film 150 may be formed on the side wall 110ST_SW of the lower wiring structure. The fluid insulating material may harden while the process is performed.

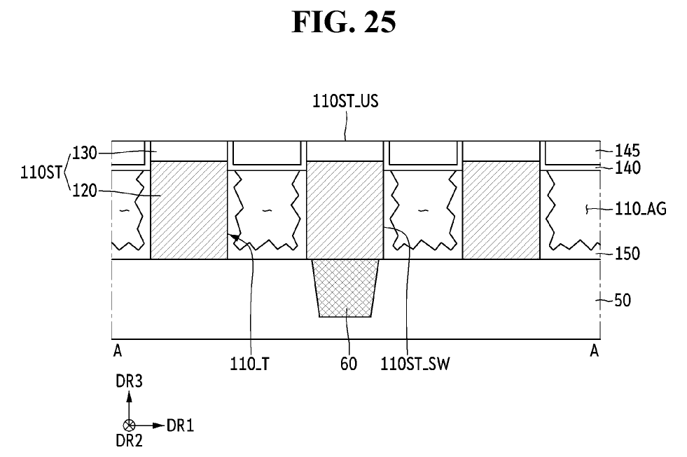

Referring to FIG. 25, the liner capping film 140 and the filling capping film 145 on the upper surface 110ST_US of the lower wiring structure may be removed.

The upper surface 110ST_US of the lower wiring structure may be exposed.

Next, referring to FIG. 2, the upper wiring structure 210ST may be formed on the lower wiring structure 110ST.

In one embodiment, a method of manufacturing a semiconductor device, the method comprising forming a lower conductive pattern, sequentially forming a metal material layer and a capping film on the lower conductive pattern, patterning the metal material layer and the capping film to form a plurality of wiring structures, each of the wiring structures including a line wiring and a wiring insulation capping film, forming a sacrificial material layer between adjacent ones of the wiring structures, the sacrificial material layer covering a portion of a side wall of each of the wiring structures, forming a liner capping film on the wiring structures and the sacrificial material layer, the liner capping film extending along an upper surface of each of the wiring structures, an upper surface of the sacrificial material layer, and a remaining portion of the side wall of each of the wiring structures, removing the sacrificial material layer to form a wiring air gap between the wiring structures, after forming the wiring air gap, depositing a flowable insulating material to form a filling capping film on the liner capping film, and forming a wiring protective film on the side wall of each of the wiring structures by allowing a portion of the flowable insulating material to pass through the liner capping film while the filling capping film is being formed.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor device comprising:
a lower conductive pattern;
a first wiring structure which is disposed on the lower conductive pattern, extends in a first direction, and includes an upper surface and a bottom surface that are opposite to each other in a second direction different from the first direction, the bottom surface of the first wiring structure facing the lower conductive pattern, the first wiring structure further including a side wall connecting the upper surface of the first wiring structure and the bottom surface of the first wiring structure; and
a first wiring protective film which is in contact with the first wiring structure, and extends along the side wall of the first wiring structure,
wherein the first wiring protective film includes a cover region that covers the side wall of the first wiring structure, and a plurality of protruding regions, and
each of the plurality of protruding regions of the first wiring protective films protrude from the cover region of the first wiring protective film in a third direction different from the first direction and the second direction.

2. The semiconductor device of claim 1, further comprising:
a liner capping film which is disposed on the first wiring protective film, and is in contact with the side wall of the first wiring structure; and
a filling capping film which is disposed on the liner capping film.

3. The semiconductor device of claim 2,
wherein the filling capping film includes a same material as the first wiring protective film.

4. The semiconductor device of claim 1, further comprising:
a second wiring structure which is disposed on the lower conductive pattern, and spaced apart from the first wiring structure in the third direction; and
a second wiring protective film which is in contact with the second wiring structure, and extends along a side wall of the second wiring structure,
wherein the side wall of the second wiring structure faces the side wall of the first wiring structure,
the second wiring protective film includes a cover region that covers the side wall of the second wiring structure, and a plurality of protruding regions protruding from the cover region of the second wiring protective film in the third direction.

5. The semiconductor device of claim 4, further comprising:
a connection wiring protective film which connects the first wiring protective film and the second wiring protective film.

6. The semiconductor device of claim 4, further comprising:
a wiring air gap which is disposed between the first wiring structure and the second wiring structure.

7. The semiconductor device of claim 1,
wherein the first wiring protective film includes an insulating material including silicon (Si) and oxygen (O).

8. The semiconductor device of claim 7,
wherein the first wiring protective film further includes at least one of carbon (C), nitrogen (N) or hydrogen (H).

9. The semiconductor device of claim 1,
wherein the first wiring structure includes a line wiring, and a wiring insulation capping film extending along an upper surface of the line wiring,
the upper surface of the first wiring structure includes an upper surface of the wiring insulation capping film, and
the bottom surface of the first wiring structure includes a bottom surface of the line wiring.

10. The semiconductor device of claim 1,
wherein the first wiring structure includes a wiring filling film, and a wiring barrier film extending along a side wall and a bottom surface of the wiring filling film.

11. A semiconductor device comprising:
a lower conductive pattern;
a first wiring structure which is disposed on the lower conductive pattern, extends in a first direction, and includes an upper surface and a bottom surface that are opposite to each other in a second direction different from the first direction, the bottom surface of the first wiring structure facing the lower conductive pattern, the first wiring structure further including a side wall connecting the upper surface of the first wiring structure and the bottom surface of the first wiring structure; and
a wiring protective film which is in contact with the first wiring structure, and extends along the side wall of the first wiring structure,
wherein a first thickness of the wiring protective film in a third direction, different from the first direction and the second direction, at a first point of the wiring protective film is greater than a second thickness of the wiring protective film in the third direction at a second point of the wiring protective film,
a third thickness of the wiring protective film in the third direction at a third point of the wiring protective film is greater than the second thickness,
a height from the bottom surface of the first wiring structure to the first point is smaller than a height from the bottom surface of the first wiring structure to the second point, and
a height from the bottom surface of the first wiring structure to the third point is greater than a height from the bottom surface of the first wiring structure to the second point.

12. The semiconductor device of claim 11,
wherein a fourth thickness of the wiring protective film in the third direction at a fourth point of the wiring protective film is smaller than the third thickness, and
a height from the bottom surface of the first wiring structure to the fourth point is greater than a height from the bottom surface of the first wiring structure to the third point.

13. The semiconductor device of claim 11, further comprising:
a liner capping film which is disposed on the wiring protective film, and extends along the side wall of the first wiring structure; and
a filling capping film disposed on the liner capping film,
wherein the liner capping film is in contact with the wiring protective film and the first wiring structure.

14. The semiconductor device of claim 13,
wherein the wiring protective film includes an insulating material including silicon (Si) and oxygen (O), and
the filling capping film includes a same material as the wiring protective film.

15. The semiconductor device of claim 11, further comprising:
a second wiring structure which is disposed on the lower conductive pattern, and spaced apart from the first wiring structure in the third direction,
wherein the wiring protective film extends along a side wall of the second wiring structure, and is in contact with the second wiring structure.

16. The semiconductor device of claim 15, further comprising:
a wiring air gap disposed between the first wiring structure and the second wiring structure.

17. The semiconductor device of claim 11,
wherein the first wiring structure includes a line wiring, and a wiring insulation capping film extending along an upper surface of the line wiring,
the upper surface of the first wiring structure includes an upper surface of the wiring insulation capping film, and
the bottom surface of the first wiring structure includes a bottom surface of the line wiring.

18. A semiconductor device comprising:
a lower conductive pattern;
a first wiring structure which is disposed on the lower conductive pattern and extends in a first direction;
a second wiring structure which extends in the first direction, and is spaced apart from the first wiring structure in a second direction perpendicular to the first direction;
a wiring protective film which is disposed on the lower conductive pattern, extends along a side wall of the first wiring structure and a side wall of the second wiring structure, and is in contact with the first wiring structure and the second wiring structure;
a wiring air gap which is disposed between the first wiring structure and the second wiring structure;
a liner capping film which is disposed on the wiring protective film and the wiring air gap, extends along the side wall of the first wiring structure and the side wall of the second wiring structure, and is in contact with the first wiring structure and the second wiring structure; and
a filling capping film which is disposed on the liner capping film between the first wiring structure and the second wiring structure,
wherein the wiring protective film includes a cover region that covers the side wall of the first wiring structure, and a plurality of protruding regions, and
each of the plurality of protruding region of the wiring protective films protrudes from the cover region of the wiring protective film in the second direction.

19. The semiconductor device of claim 18,
wherein the wiring air gap is covered by the wiring protective film and the liner capping film in a cross-sectional view of the semiconductor device.

20. The semiconductor device of claim 18,
wherein the first wiring structure includes an upper surface and a bottom surface that are opposite to each other in a third direction perpendicular to the first direction and the second direction,
the bottom surface of the first wiring structure faces the lower conductive pattern,
a width of the upper surface of the first wiring structure in the second direction is smaller than or equal to a width of the bottom surface of the first wiring structure in the second direction.
